(19) United States
(12) Patent Application Publication
(10) Pub. No.: US 2009/0072355 A1
(43) Pub. Date: Mar. 19, 2009

(54) DUAL SHALLOW TRENCH ISOLATION STRUCTURE

(75) Inventors: Kangguo Cheng, Beacon, NY (US); Lisa F. Edge, State College, PA (US); Johnathan E. Faltermeier, Fishkill, NY (US); Naoyoshi Kusaba, Hopewell Junction, NY (US)

Correspondence Address: SCULLY, SCOTT, MURPHY & PRESSER, P.C., 400 GARDEN CITY PLAZA, Suite 300, GARDEN CITY, NY, 11530, US

(73) Assignee: INTERNATIONAL BUSINESS MACHINES CORPORATION, Armonk, NY (US)

(21) Appl. No.: 11/856,260

(22) Filed: Sep. 17, 2007

(51) Int. Cl. H01L 29/06; H01L 21/311

(52) U.S. Cl. 257/622; 438/702; 257/E21.249; 257/E29.005

(57) ABSTRACT

A protective dielectric layer is formed on a first shallow trench having straight sidewalls, while exposing a second shallow trench. An oxidation barrier layer is formed on the semiconductor substrate. A resist is applied and recessed within the second shallow trench. The oxidation barrier layer is removed above the recessed resist. The resist is removed and thermal oxidation is performed so that a thermal oxide collar is formed above the remaining oxidation mask layer. The oxidation barrier layer is thereafter removed and exposed semiconductor area therebelow depth is etched to form a bottle shaped shallow trench. The first and the bottle shaped trenches are filled with a dielectric material to form a straight sidewall shallow trench isolation structure and a bottle shallow trench isolation structure, respectively. Both shallow trench isolation structures may be employed to provide optimal electrical isolation and device performance to semiconductor devices having different depths.

### FIELD OF THE INVENTION

The present invention relates to a semiconductor structure, and particularly to a semiconductor structure containing a straight sidewall shallow trench isolation structure and a bottled shallow trench isolation structure, and methods of manufacturing the same.

### BACKGROUND OF THE INVENTION

Typical semiconductor devices in a complementary metal-oxide-semiconductor (CMOS) circuit are formed in a p-well or an n-well in a semiconductor substrate. Since other semiconductor devices are also present in the semiconductor substrate, the semiconductor device requires electrical isolation from adjacent semiconductor devices. Electrical isolation is typically provided by isolation structures that employ trenches filled with an insulator material. Electrical isolation of the semiconductor device from other devices located in the same well is called intra-well isolation. Electrical isolation of the semiconductor device from other devices in an adjacent well of the opposite type is called inter-well isolation.

In both cases, unintended functionality of parasitic devices, such as parasitic pnp or npn bipolar transistors, formed by various elements of the semiconductor device and adjacent semiconductor devices, needs to be suppressed by placing a dielectric material, typically in the form of shallow trench isolation structures, in the current paths among the elements of the parasitic devices.

Conventional shallow trench isolation structures comprise a dielectric material formed in a shallow trench having a bottom surface and trench sidewalls. The trench sidewalls are typically straight sidewalls, i.e., planar surfaces with a vertical cross-section of a straight line, and may be substantially vertical or may have a small taper, deviating from a vertical line typically by less than 10 degrees, to facilitate a fill process with a dielectric material. The vertical distance between the bottom surface of the shallow trench and a top surface of a semiconductor substrate in which the shallow trench is formed is referred to as the depth of the shallow trench.

Semiconductor structures having multiple depths may be formed on the semiconductor substrate. Depending on the nature and the depths of other semiconductor structures around the semiconductor structures, the width, or the lateral dimension of the conventional shallow trench isolation structures are adjusted to provide a suitable level of electrical isolation, while minimizing the area occupied by the shallow trench isolation structure and maximizing the area for semiconductor devices.

U.S. Pat. No. 6,787,423 to Xiang provides a shallow trench isolation structure in which a bottle shaped shallow trench isolation structure, i.e., a shallow trench isolation structure having a wider lower portion than an upper portion, is employed. A field effect transistor is located above the lower portion of the bottle shaped shallow trench isolation structure. The widened bottom portion of the bottle shaped shallow trench isolation structure provides an extended length between adjacent semiconductor devices, enhancing electrical isolation between adjacent semiconductor devices.

While some semiconductor devices may benefit from the structures disclosed in the '423 patent through an improvement in electrical isolation and/or and increase in the semiconductor device area, some other semiconductor devices extend deeper than the depth of the upper portion of the bottled shallow trench isolation structures. For semiconductor devices extending below the upper portion of the bottled shallow trench isolation structures, the semiconductor device area above the lower portion of the bottled shallow trench isolation structures adds to device capacitance. For these devices, a shallow trench isolation structure having straight sidewalls is preferred for device performance.

In view of the above, there exists a need for a semiconductor structure containing both a bottle shaped shallow trench isolation structure and a straight sidewall shallow trench isolation structure.

Further, there exists a need for a semiconductor structure having a bottle shaped shallow trench structure between shallow semiconductor devices, and having a straight sidewall shallow trench isolation structure between deep semiconductor devices.

### SUMMARY OF THE INVENTION

The present invention addresses the needs described above by providing a semiconductor containing a straight sidewall shallow trench isolation structure and a bottled shallow trench isolation structure, and methods of manufacturing the same.

Specifically, a first shallow trench and a shallow trench, both having straight sidewalls and having a first depth, are formed in a semiconductor substrate. A protective dielectric layer is deposited and patterned to cover the first shallow trench, while exposing the second shallow trench. An oxidation barrier layer is formed on the semiconductor substrate. A resist is applied and recessed within the second shallow trench to a second depth. The oxidation barrier layer is removed above the recessed resist. The resist is removed and thermal oxidation is performed so that a thermal oxide collar is formed above the second depth within the second shallow trench. The oxidation barrier layer is removed and the exposed portion of the semiconductor substrate below the second depth is etched to form a bottle shaped shallow trench. The thermal oxide collar and the protective dielectric layer are removed. The first and the bottle shaped trenches are filled with a dielectric material to form a straight sidewall shallow trench isolation structure and a bottle shallow trench isolation structure, respectively.

Shallow semiconductor structures having depths up to the second depth may be formed around the bottle shallow trench isolation structure, while deep semiconductor structures having depths exceeding the second depth may be formed around the straight sidewall shallow trench isolation structure. The inventive semiconductor structure provides increased electrical isolation between the shallow semiconductor structures and increased semiconductor device area for shallow semiconductor structures, while providing necessary depth and enabling optimal semiconductor device structures for the deep semiconductor structures.

According to one aspect of the present invention, a method of manufacturing a semiconductor structure is provided, which comprises:

forming a trench having a first depth and containing a pair of substantially planar trench sidewalls in a semiconductor substrate;

forming an oxidation barrier layer on a lower portion of the pair of substantially planar trench sidewalls;

forming a thermal oxide collar on an upper portion of the pair of substantially planar trench sidewalls above a second depth, wherein the pair of substantially planar trench sidewalls becomes separated by an upper portion width within the upper portion; and

etching the lower portion of the pair of substantially planar trench sidewalls below the second depth to form another pair of substantially planar trench sidewalls separated by a lower portion width, wherein the lower portion width is greater than the upper portion width.

In one embodiment, the method further comprises removing the oxidation barrier layer from the lower portion of the pair of substantially planar trench sidewalls after the forming of the thermal oxide collar and prior to the etching of the lower portion of the pair of substantially planar trench sidewalls.

In another embodiment, the forming of the oxidation barrier layer on the lower portion of the pair of substantially planar trench sidewalls comprises:

forming the oxidation barrier layer on the entirety of the pair of substantially planar trench sidewalls within the trench; and

removing a portion of the oxidation barrier layer on the upper portion of the pair of substantially planar trench sidewalls.

In yet another embodiment, the method further comprises:

filling the trench with a resist after the forming of the oxidation barrier layer on the entirety of the pair of substantially planar trench sidewalls; and

recessing the resist down to the second depth.

In still another embodiment, the method further comprises forming a dielectric pad layer directly on a top surface of the semiconductor substrate prior to the forming of the trench, wherein the dielectric pad layer is resistant to thermal oxidation.

In still yet another embodiment, the semiconductor substrate comprises silicon, the thermal oxide collar comprises silicon oxide, and the oxidation barrier layer comprises silicon nitride, and the dielectric pad layer comprises silicon nitride.

In a further embodiment, the etching of the lower portion is substantially isotropic, wherein the etching of the lower portion forms a trench bottom wall at a third depth, and wherein the lower portion width less the upper portion width is substantially the same as twice the third depth less the first depth.

In an even further embodiment, the method further comprises:

forming another trench having the first depth and containing a third pair of substantially planar trench sidewalls in the semiconductor substrate at the same step as the forming of the trench; and

forming a protective dielectric layer within the another trench prior to the forming of the oxidation mask layer.

In a yet further embodiment, the method further comprises:

forming the protective dielectric layer within the trench; and

removing the protective dielectric layer within the trench from within the trench prior to the forming of the oxidation mask layer.

In a still further embodiment, the method further comprises:

filling the trench and the another trench with a dielectric material;

planarizing the dielectric material employing a dielectric pad layer as a stopping layer; and

recessing the dielectric material to a height that is substantially flush with a top surface of the semiconductor substrate.

In further another embodiment, the protective dielectric layer and the thermal oxide collar comprise silicon oxide, and the protective dielectric layer and the thermal oxide collar are removed at the same etch step.

According to another aspect of the present invention, a semiconductor structure is provided, which comprises:

a first shallow trench isolation (STI) structure comprising a dielectric material, located in a semiconductor substrate, and containing a first pair of substantially planar STI sidewalls separated by a first width and a first STI bottom surface located at a first depth, wherein the first pair of substantially planar STI sidewalls extends from a top surface of the semiconductor substrate to the first STI bottom surface; and

a second shallow trench isolation (STI) structure comprising the dielectric material and located in the semiconductor substrate and having an upper portion and a lower portion, wherein the upper portion contains a second pair of substantially planar STI sidewalls separated by a second width and extending from the top surface to a second depth, and wherein the lower portion contains a third pair of substantially planar STI sidewalls separated by a third width and extending from the second depth to a third depth and adjoining a second STI bottom surface at the third depth, and wherein the third width is greater than the second width.

According to yet another aspect of the present invention, another semiconductor structure is provided, which comprises:

a first trench located in a semiconductor substrate and containing a first pair of substantially planar trench sidewalls separated by a first width and a first trench bottom surface located at a first depth, wherein the first pair of substantially planar trench sidewalls extends from a top surface of the semiconductor substrate to the first trench bottom surface; and

a second trench located in the semiconductor substrate and having an upper portion and a lower portion, wherein the upper portion contains a second pair of substantially planar trench sidewalls separated by a second width and extending from the top surface to a second depth, and wherein the lower portion contains a third pair of substantially planar trench sidewalls separated by a third width and extending from the second depth to a third depth and adjoining a second trench bottom surface at the third depth, and wherein the third width is greater than the second width.

In one embodiment, the third depth is greater than the first depth, and the second depth is less than the first depth.

In another embodiment, the third width less the second width is less than twice the third depth less the first depth.

In yet another embodiment, the first trench/STI bottom surface and the second trench/STI bottom surface are substantially horizontal and planar.

In a further embodiment, the semiconductor structures may further comprise:

at least one semiconductor device abutting the first pair of substantially planar STI sidewalls and extending from the top surface to a depth below the second depth; and

at least another semiconductor device abutting the second pair of substantially planar STI sidewalls and located above the second depth.

### BRIEF DESCRIPTION OF THE DRAWINGS

FIGS. 1-12 show sequential vertical cross-sectional views of a first exemplary semiconductor structure according to a first embodiment of the present invention at various stages of a manufacturing sequence.

FIG. 13 shows a top-down view of the first exemplary semiconductor structure shown in FIG. 12.

FIGS. 14-16 show sequential vertical cross-sectional views of a second exemplary semiconductor structure according to a second embodiment of the present invention at various stages of a manufacturing sequence.

### DETAILED DESCRIPTION OF THE INVENTION

As stated above, the present invention relates to a semiconductor structure containing a straight sidewall shallow trench isolation structure and a bottled shallow trench isolation structure, and methods of manufacturing the same, which are now described in detail with accompanying figures. It is noted that like and corresponding elements are referred to by like reference numerals.

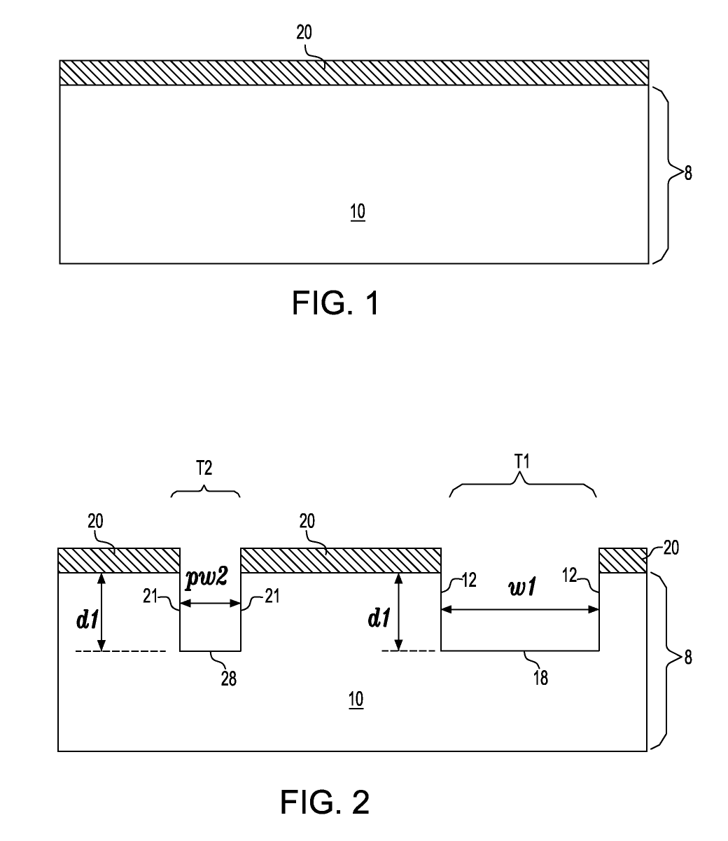

Referring to FIG. 1, a first exemplary semiconductor structure according to a first embodiment of the present invention comprises a semiconductor substrate 8 containing a substrate layer 10 and a dielectric pad layer 20. The substrate layer 10 may comprise a silicon containing semiconductor such as silicon, silicon-carbon alloy, silicon germanium alloy, or silicon-carbon-germanium alloy. Other semiconductor materials such as GaAs, InAs, InP, other III-V compound semiconductors, or II-VI compound semiconductors may be employed as well. The substrate layer 10 may be p-doped or n-doped, i.e., may have more of p-type dopants than n-type dopants or vice versa.

The semiconductor material in the substrate layer 10 is capable of forming a thermal oxide. For example, the semiconductor material may be silicon and the thermal oxide may be silicon oxide. In case the semiconductor material comprises a germanium alloy, the thermal oxide may contain germanium oxide.

Preferably, the dielectric pad layer 20 comprises a dielectric material that is resistive to permeation of oxygen. For example, the dielectric pad layer 20 may comprise silicon nitride. The dielectric pad layer 20 may comprise a stack of heterogeneous dielectric material in which at least one is resistant to permeation of oxygen. For example, the dielectric pad layer 20 may comprise a stack of silicon oxide and silicon nitride. The thickness of the dielectric pad layer 20 may be from about 20 nm to about 200 nm, and typically from about 50 nm to about 150 nm, although greater and lesser thicknesses are also contemplated.

While the present invention is described employing a bulk substrate, the present invention may also be practiced with a semiconductor-on-insulator (SOI) substrate or with a hybrid substrate having a bulk portion and an SOI portion. Such variations are explicitly contemplated herein.

Referring to FIG. 2, a first trench T1 and a second trench T2 are formed in the semiconductor substrate 8. The first trench T1 and the second trench T2 may be formed, for example, by applying a photoresist (not shown) on the dielectric pad layer 20 followed by lithographically patterning and etching the photoresist. The pattern in the photoresist is thereafter transferred into the dielectric pad layer 20 and into the semiconductor substrate.

The first trench T1 comprises a first pair of trench sidewalls 12 and a first trench bottom surface 18. Each of the first pair of substantially planar trench sidewalls 12 is substantially planar, i.e., has a surface having substantially the same form as a plane and does not have a kink or a substantial curvature. The first pair of trench sidewalls 12 may be substantially vertical, or may have a taper, deviating from a vertical line typically by less than 10 degrees. The first pair of trench sidewalls 12 are parallel to each other to the extent that any taper, or slope from a vertical line is overlooked. The second trench T2 comprises a second pair of trench sidewalls 21 having the same properties as the first pair of substantially planar trench sidewalls 12 as described above.

The first pair of trench sidewalls 12 are separated by a first width w1, and the second pair of trench sidewalls 21 are separated by a preliminary second width pw2. The first trench T1 has a first trench bottom surface 18, and the second trench T2 has a second trench bottom surface 28, respectively. Both the first trench bottom surface 18 and the second trench bottom surface 28 are located at a first depth d1 from the interface between the semiconductor substrate 8 and the dielectric pad layer 20. The interface is also a top surface of the semiconductor substrate 8.

The first depth d1 is in the range of depths of conventional shallow trench isolation structures, and may be from about 150 nm to about 500 nm, and typically from about 200 nm to about 350 nm.

Not necessarily but preferably, the first width w1 is greater than the preliminary second width pw2. The first width w1 is typically from about 100 nm to about 2,000 nm and the preliminary second width pw2 is typically from about 70 nm to about 500 nm, although greater and lesser first widths w1 and greater and lesser preliminary second widths pw2 are explicitly contemplated herein.

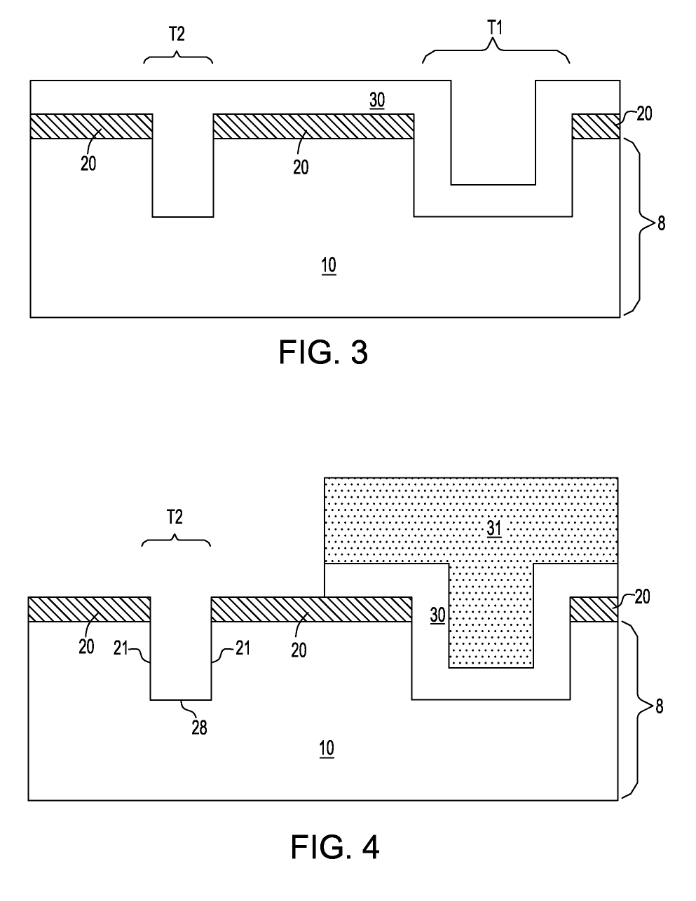

Referring to FIG. 3, a protective dielectric layer 30 is formed on the dielectric pad layer 20, in the first trench T1, and in the second trench. The protective dielectric material layer 30 may comprise an oxide or a nitride. The protective dielectric material layer 30 may, or may not, comprise the same material as the dielectric pad layer 20. Preferably, the protective dielectric material layer 30 is a different material from the dielectric pad layer 20. For example, the dielectric pad layer 20 may comprise silicon nitride and the protective dielectric material layer 30 may comprise a chemical vapor deposition (CVD) oxide such as TEOS oxide, undoped silicate glass (USG), phosphosilicate glass (PSG), etc. The thickness of the protective dielectric material layer 30 may be from about 30 nm to about 200 nm, and typically from about 50 nm to about 150 nm, although greater and lesser thicknesses are also contemplated.

Referring to FIG. 4, a photoresist 31 is applied over the protective dielectric layer 30 and lithographically patterned to expose the second trench T2, while covering the first trench T1. A reactive ion etch and/or a wet etch is performed to remove the portion of the protective dielectric layer 30 above the second trench T2. After exposing the second pair of trench sidewalls 21 and the second trench bottom surface 28, the photoresist 31 is removed. The first trench T1 remains covered with the protective dielectric layer 30.

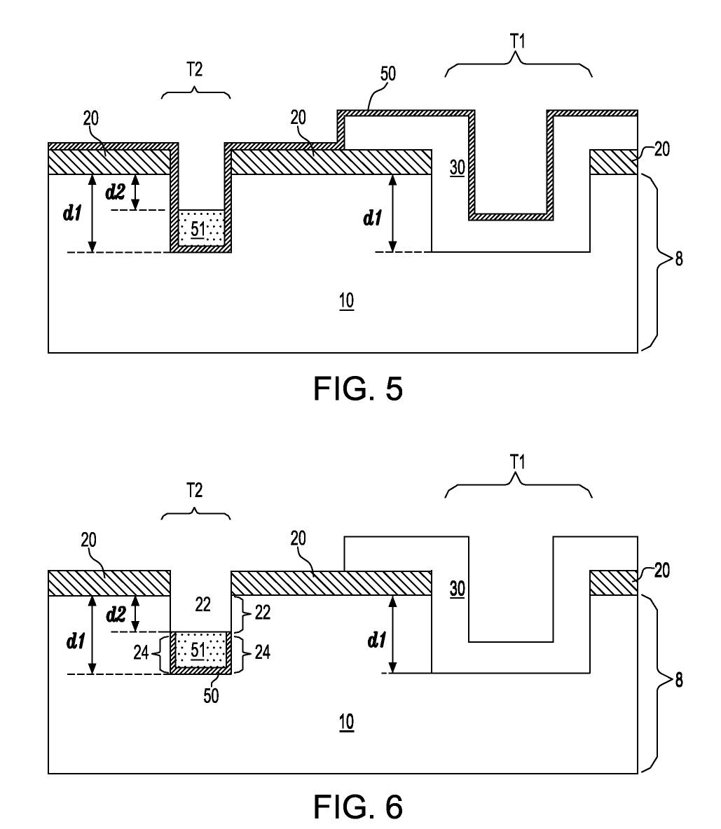

Referring to FIG. 5, an oxidation barrier layer 50 is formed on all outer surfaces of the first exemplary structure including the entirety of the second pair of trench sidewalls 21 and the second trench bottom surface 28. The oxidation barrier layer 50 comprises a material that is resistant to permeation of oxygen. For example, the oxidation barrier layer 50 may comprise silicon nitride. During a subsequent thermal oxidation process, the oxidation barrier layer 50 prevents oxidation of the semiconductor material directly beneath the oxidation barrier layer 50. The oxidation barrier layer 50 may be formed, for example, by a conformal chemical vapor deposition (CVD) such as low pressure chemical vapor deposition (LPCVD). The thickness of the oxidation barrier layer 50 may be from about 3 nm to about 30 nm.

A resist 51 is applied on the oxidation barrier layer 50 and planarized. The resist 51 may, or may not, be photosensitive. The resist 51 may comprise a polymer material. The resist 51 is thereafter recessed to a second depth d2 that is less than the first depth d1. The second depth d2 may be from about 50 nm to about 350 nm, and typically from about 100 nm to about 200 nm. A lower portion of the second trench T2 below the second depth d2 is filled with the resist 51. The resist 51 may, or may not, be present in the first trench T1. However, presence or absence of the resist 51 in the first trench T1 is immaterial to practice of the present invention since the protective dielectric layer 30 protects the first pair of trench sidewalls 12 from any subsequent etching.

Referring to FIG. 6, the portion of the oxidation barrier layer 50 is removed from an upper portion of the second pair of trench sidewalls 22 by an isotropic etch. In case the oxidation barrier layer 50 comprises silicon nitride, a wet etch employing a hot phosphoric acid may be employed. The portion of the oxidation barrier layer 50 on the lower portion of the second pair of trench sidewalls 24 below the second depth is protected from the isotropic etch by the resist 51. The upper portion of the second pair of trench sidewalls 22 above the second depth d2 is exposed after the isotropic etch. The resist 51 is thereafter removed, for example, by ashing.

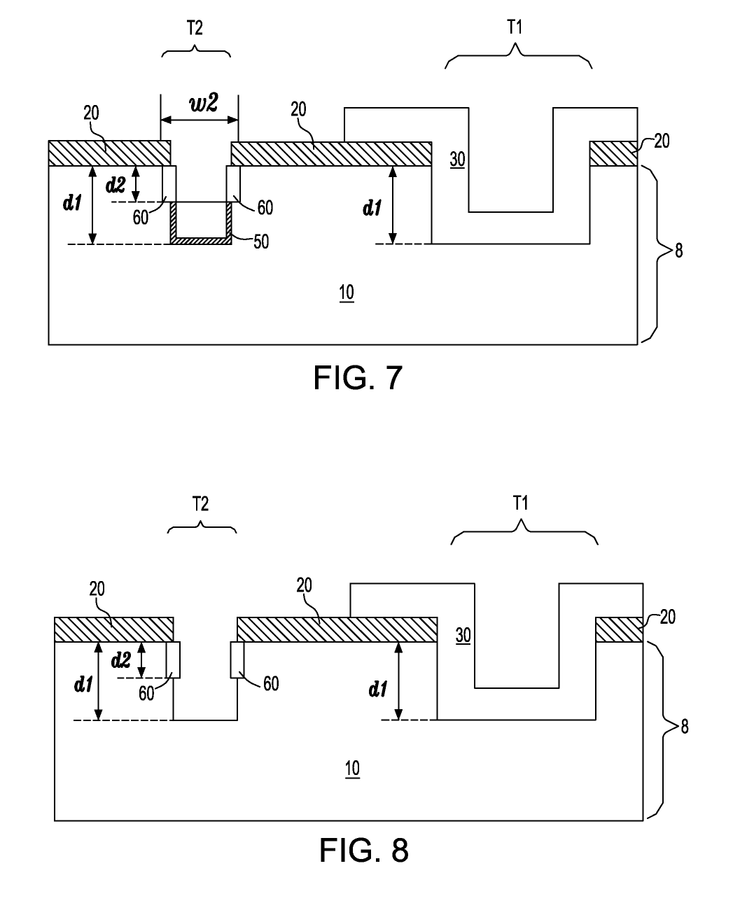

Referring to FIG. 7, a thermal oxidation is performed at an elevated temperature and in an oxidizing environment. A thermal oxide collar 60 is formed on the upper portion of the second pair of trench sidewalls 22 by thermal conversion of the semiconductor material into a thermal oxide. For example, the substrate layer 10 may comprise silicon and the thermal oxide collar 60 may comprise silicon oxide. In case the substrate layer 10 comprises a germanium alloy, the thermal oxide may contain a germanium oxide compound. In case the substrate layer 10 comprises a compound semiconductor material, the substrate layer 10 comprises an oxide containing the elements of the compound semiconductor material. The oxidation barrier layer 50 prevents formation of a thermal oxide from underneath by blocking diffusion of oxygen during a thermal oxidation process. The thickness of the thermal oxide collar 60 may be from about 3 nm to about 30 nm, although greater and lesser thicknesses are contemplated.

Process conditions for the thermal oxidation process vary depending on the material and thickness of the thermal oxide collar 60. The temperature range may be from about 400° C. to about 1,000° C., and typically from about 600° C. to about 800° C. Oxygen partial pressure during the thermal oxidation process may be from about 10 mTorr to about 20 atm. Duration of the thermal oxidation process at the oxidizing conditions may be from about 5 seconds to about 60 minutes. Since the thermal oxidation process consumes the semiconductor material beneath the upper portion of the second pair of trench sidewalls 22, the upper portion of the second pair of trench sidewalls 22 moves inward into the substrate layer during the thermal oxidation process. The separation between the upper portion of the second pair of trench sidewalls 22 is a second width w2, which is greater than the preliminary second width pw2.

Referring to FIG. 8, the remaining portion of the oxidation barrier layer 50 on the lower portion of the second trench T2 is removed by an etch. The etch may be an isotropic etch that is selective to the thermal oxide collar 60. For example, the oxidation barrier layer 50 may comprise silicon nitride and the etch may be a wet etch employing a hot phosphoric acid that etches silicon nitride selective to silicon oxide.

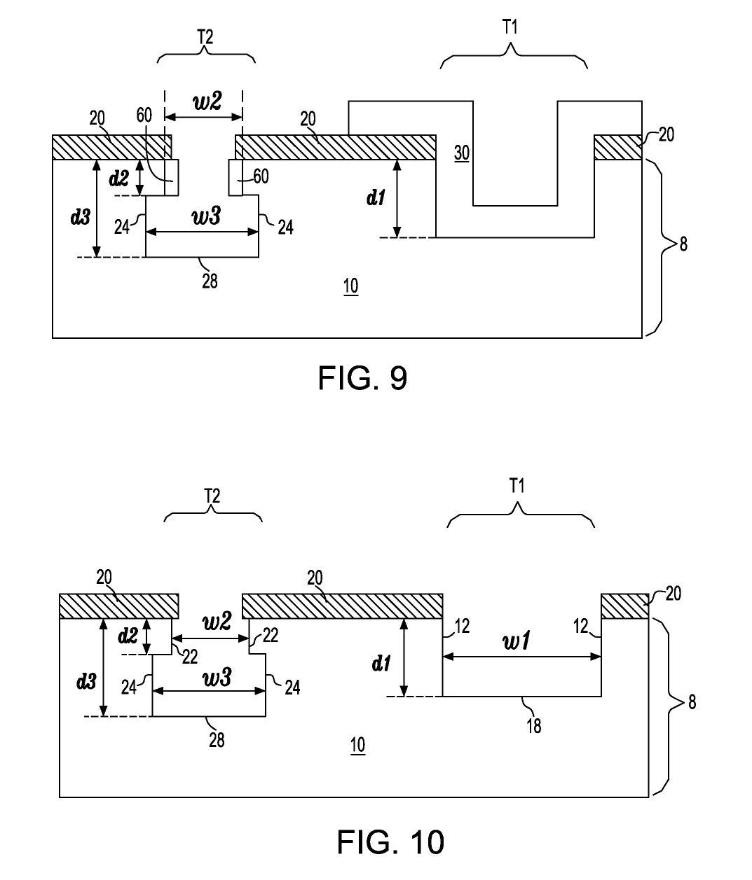

Referring to FIG. 9, an etch is performed to remove the semiconductor material of the substrate layer 10 selective to the thermal oxide collar 60. Preferably, the etch is an isotropic etch. The etch may be an isotropic reactive ion etch or a wet etch. Reactive ion etch chemistries and wet etch chemistries for etching a semiconductor material selective to a thermal oxide derived therefrom are well known in the art. The lower portion of the second trench expands laterally as the semiconductor material is removed by the etch from underneath the lower portion of the second pair of trench sidewalls 24. Further, the second trench becomes deeper as the second trench bottom surface 28 is etched. The second trench bottom surface 28 is substantially horizontal and planar.

The separation between the lower portion of the second pair of trench sidewalls 24 after the etch is a third width w3, which is greater than the second width w2. The depth of the second trench, i.e., the depth of the second bottom surface 28, after the etch is a third depth d3, which is greater than the first width d1. In case the etch is isotropic, the third width w3 less the preliminary second width pw2 is substantially the same as twice the third depth d3 less the first depth d1, while the third width w3 less the second width w2 is less than twice the third depth d3 less the first depth d1. The difference between the third depth d3 and the first depth d1 may be from about 20 nm to about 150 nm, and typically from about 30 nm to about 80 nm.

Referring to FIG. 10, the thermal oxide collar 60 and the protective dielectric layer 30 are removed, for example, by a wet etch. In case the thermal oxide collar 60 and/or the protective dielectric layer 30 comprises silicon oxide, a wet etch employing a hydrofluoric acid (HF) may be used.

The first exemplary semiconductor structure in FIG. 10 comprises:

a first trench T1 located in a semiconductor substrate 8 and containing a first pair of substantially planar trench sidewalls 12 separated by a first width w1 and a first trench bottom surface 18 located at a first depth d1, wherein the first pair of substantially planar trench sidewalls 12 extends from a top surface of the semiconductor substrate 8 to the first trench bottom surface 18; and

a second trench T2 located in the semiconductor substrate 8 and having an upper portion and a lower portion, wherein the upper portion contains “a second pair of substantially planar trench sidewalls,” which is the upper portion of the second pair of trench sidewalls 22, separated by a second width w2 and extending from the top surface to a second depth d2, and wherein the lower portion contains “a third pair of substantially planar trench sidewalls,” which is the lower portion of the second pair of trench sidewalls 24, separated by a third width w3 and extending from the second depth d2 to a third depth d3 and adjoining a second trench bottom surface 28 at the third depth d3, and wherein the third width w3 is greater than the second width w2.

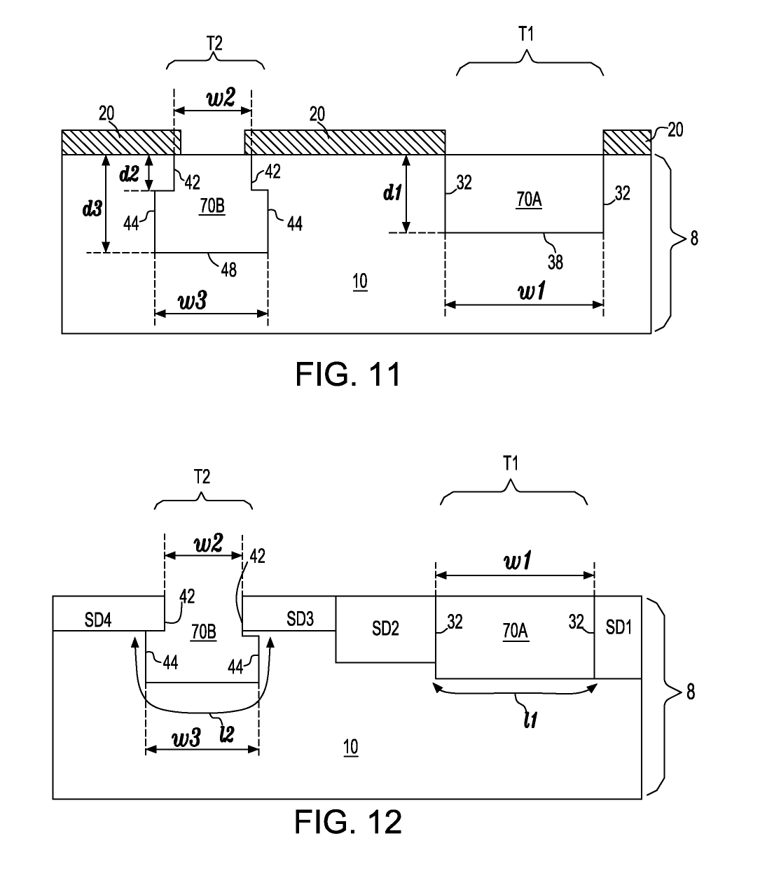

Referring to FIG. 11, the first trench T1 and the second trench T2 are filled with a dielectric material such as silicon oxide or silicon nitride. A chemical vapor deposition process such as high density plasma chemical vapor deposition (HDPCVD) or plasma enhanced chemical vapor deposition (PECVD) may be employed to deposit the dielectric material into the first trench T1 and the second trench T2. Optionally, at least one dielectric liner comprising another dielectric material may be formed on the trench sidewalls (12, 22, 24) prior to depositing the dielectric material. Deposition and partial etching of the dielectric material may be repeated to enhance the gap fill properties of the deposited dielectric material.

Sufficient amount of the dielectric material is deposited to fill the first trench T1 and the second trench T2. The thickness of the dielectric material is preferably greater than the lesser of half of the first width w1 and the sum of the first depth d1 and the thickness of the dielectric pad layer 20. Also, the thickness of the dielectric material is preferably greater than the lesser of half of the second width w2 and the sum of the third depth d3 and the thickness of the dielectric pad layer 20. The dielectric material is planarized, for example, by chemical mechanical planarization (CMP). The dielectric pad layer 20 may be employed as a stopping layer during the CMP. Typically, the dielectric material is further recessed below the surface of the dielectric pad layer 20. The recessed surfaces of the dielectric material filling the first trench T1 and the second trench T2 may be substantially flush with a top surface of the semiconductor substrate 8.

The portion of the dielectric material in the first trench T1 constitutes a first shallow trench isolation (STI) structure 70A, while the portion of the dielectric material in the second trench T2 constitutes a second shallow trench isolation (STI) structure. A first pair of STI sidewalls 32 abuts the first pair of trench sidewalls 12 in the first trench T1. A second pair of STI sidewalls 42 abuts the upper portion of the second pair of trench sidewalls 22, and a third pair of STI sidewalls 44 abuts the lower portion of the second pair of trench sidewalls 24 in the second trench T2. The first STI structure is a conventional “straight sidewall STI structure.” The second STI structure is a “bottle shaped STI structure,” i.e., an STI structure having a wider lower portion than an upper portion. The first exemplary semiconductor comprises both a straight sidewall STI structure, which is the first STI structure 70A, and a bottle shaped STI structure, which is the second STI structure 70B in the same semiconductor substrate 8.

The first exemplary structure in FIG. 11 comprises:

a first shallow trench isolation (STI) structure 70A comprising a dielectric material, located in a semiconductor substrate 8, and containing a first pair of substantially planar STI sidewalls 32 separated by a first width w1 and a first STI bottom surface 38 located at a first depth d1, wherein the first pair of substantially planar STI sidewalls 32 extends from a top surface of the semiconductor substrate 8 to the first STI bottom surface 38; and

a second shallow trench isolation (STI) structure 70B comprising the dielectric material and located in the semiconductor substrate 8 and having an upper portion and a lower portion, wherein the upper portion contains a second pair of substantially planar STI sidewalls 42 separated by a second width w2 and extending from the top surface to a second depth d2, and wherein the lower portion contains a third pair of substantially planar STI sidewalls 44 separated by a third width w3 and extending from the second depth d2 to a third depth d3 and adjoining a second STI bottom surface 48 at the third depth d3, and wherein the third width w3 is greater than the second width w2.

Referring to FIG. 12, at least one semiconductor device extending from the surface of the semiconductor substrate 8 to a depth greater than the second depth d2 may be formed directly on the first pair of substantially planar STI sidewalls 32. Similarly, at least another semiconductor device extending from the surface of the semiconductor substrate 8 to a depth not exceeding the second depth d2 may be formed directly on the second pair of substantially planar STI sidewalls 42. Specifically, a first semiconductor device SD1 and a second semiconductor device SD2 abut the first pair of substantially planar STI sidewalls 32 and extend to depths greater than the second depth d2. A third semiconductor device SD3 and a fourth semiconductor device SD4 abut the second pair of substantially planar STI sidewalls 42 but does not extend to depths greater than the second depth d2. A shallow semiconductor device herein denotes a semiconductor device extending to a depth not greater than the second depth d2, while a deep semiconductor device herein denotes a semiconductor device extending to a depth greater than the second depth d2.

Examination of the first and second semiconductor devices (SD1, SD1) shows that deep semiconductor devices extending below the second depth would consume more semiconductor area and/or have extraneous parasitic capacitance if all shallow trench isolation structures were like the second STI structure 70B. For semiconductor devices separated by the first STI structure 70A, the electrical isolation length l1 is substantially the same as in a conventional shallow trench isolation structure. For semiconductor devices separated by the second STI structure 70B, the electrical isolation length 12 increases by the difference between the third width w3 and the second width w2.

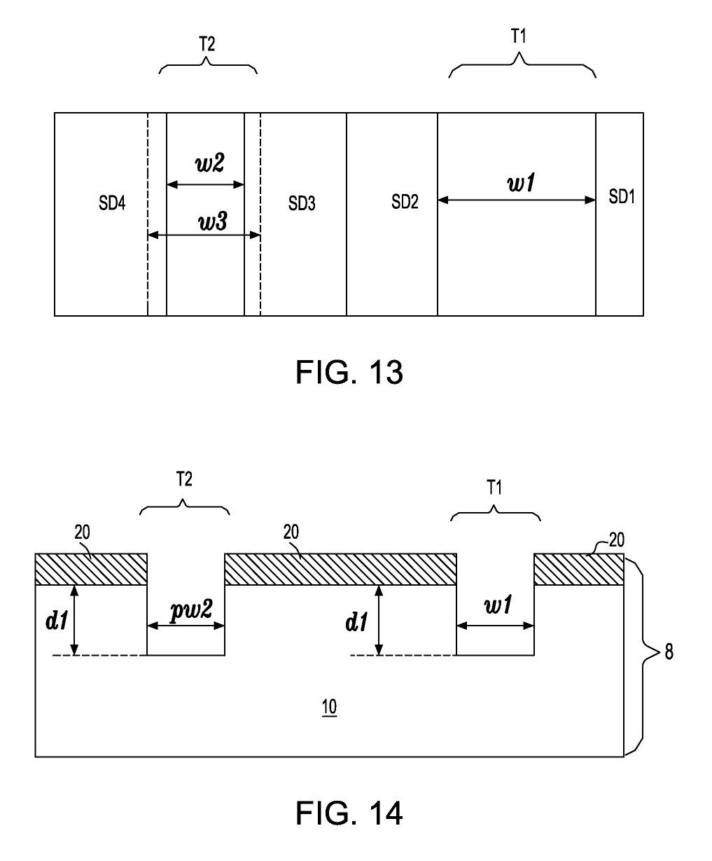

Referring to FIG. 13, a top down view of the first exemplary semiconductor structure shows that for the third semiconductor device SD3 and the fourth semiconductor device SD4, the physical distance between the two semiconductor devices (SD3, SD4) is w2, while a lateral electrical isolation distance between the two semiconductor devices (SD3, SD4) is w3. Thus, the present invention provides longer electrical isolation between shallow semiconductor devices not extending below the second depth d2, while increasing available area for forming such shallow semiconductor devices.

Referring to FIG. 14, a second exemplary semiconductor structure according to a second embodiment of the present invention comprises a first trench T1 and the second trench T2 as in the first exemplary structure shown in FIG. 2. The first width w1 may, or may not, be less than the preliminary second width pw2. The first width w1 is typically from about 50 nm to about 300 nm and the preliminary second width pw2 is typically from about 70 nm to about 500 nm, although greater and lesser first widths w1 and greater and lesser preliminary second widths pw2 are explicitly contemplated herein.

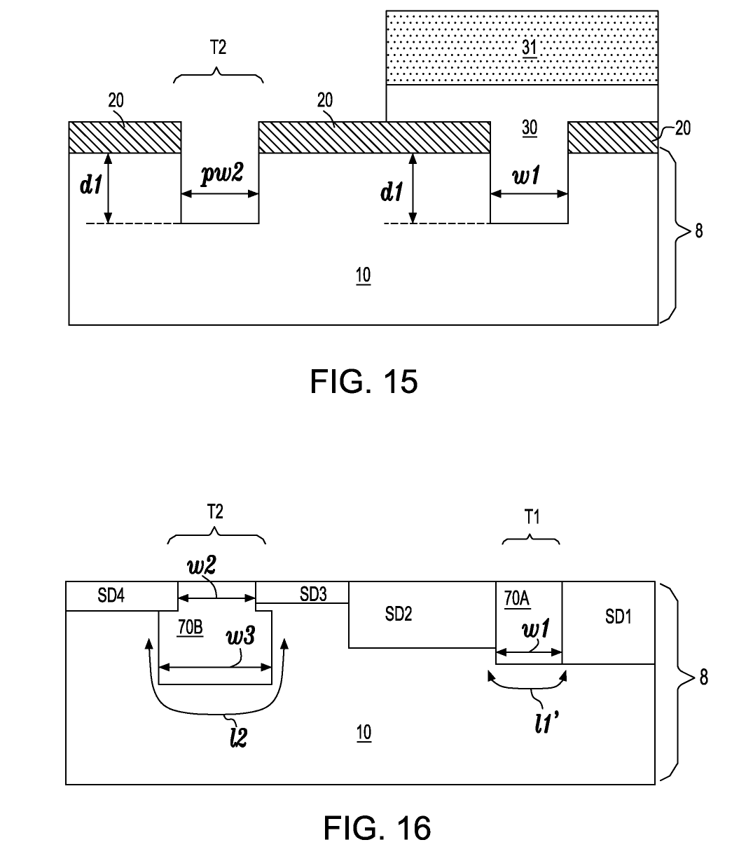

As shown in FIG. 15, the first width w1 is less than twice the thickness of the protective dielectric layer 30. Thus, the first trench T1 is fully filled with the protective dielectric layer 30 prior to the application of the photoresist 31. The same processing steps are employed in the second embodiment as in the first embodiment.

Referring to FIG. 16, the second exemplary semiconductor structure is shown at a processing step corresponding to FIG. 12 in the first embodiment. Compared to the first exemplary semiconductor structure, a shorter electrical isolation length l1′ compared to the electrical isolation length l1 in the first semiconductor structure is enabled.

While the invention has been described in terms of specific embodiments, it is evident in view of the foregoing description that numerous alternatives, modifications and variations will be apparent to those skilled in the art. Accordingly, the invention is intended to encompass all such alternatives, modifications and variations which fall within the scope and spirit of the invention and the following claims.

What is claimed is:

1. A method of manufacturing a semiconductor structure, comprising:
forming a trench having a first depth and containing a pair of substantially planar trench sidewalls in a semiconductor substrate;
forming an oxidation barrier layer on a lower portion of said pair of substantially planar trench sidewalls;
forming a thermal oxide collar on an upper portion of said pair of substantially planar trench sidewalls above a second depth, wherein said pair of substantially planar trench sidewalls becomes separated by an upper portion width within said upper portion; and
etching said lower portion of said pair of substantially planar trench sidewalls below said second depth to form another pair of substantially planar trench sidewalls separated by a lower portion width, wherein said lower portion width is greater than said upper portion width.

2. The method of claim 1, further comprising removing said oxidation barrier layer from said lower portion of said pair of substantially planar trench sidewalls after said forming of said thermal oxide collar and prior to said etching of said lower portion of said pair of substantially planar trench sidewalls.

3. The method of claim 2, wherein said forming of said oxidation barrier layer on said lower portion of said pair of substantially planar trench sidewalls comprises:
forming said oxidation barrier layer on the entirety of said pair of substantially planar trench sidewalls within said trench; and
removing a portion of said oxidation barrier layer on said upper portion of said pair of substantially planar trench sidewalls.

4. The method of claim 3, further comprising:
filling said trench with a resist after said forming of said oxidation barrier layer on said entirety of said pair of substantially planar trench sidewalls; and
recessing said resist down to said second depth.

5. The method of claim 1, further comprising forming a dielectric pad layer directly on a top surface of said semiconductor substrate prior to said forming of said trench, wherein said dielectric pad layer is resistant to thermal oxidation.

6. The method of claim 5, wherein said semiconductor substrate comprises silicon, said thermal oxide collar comprises silicon oxide, and said oxidation barrier layer comprises silicon nitride, and said dielectric pad layer comprises silicon nitride.

7. The method of claim 1, wherein said etching of said lower portion is substantially isotropic, wherein said etching of said lower portion forms a trench bottom wall at a third depth, and wherein said lower portion width less said upper portion width is substantially the same as twice said third depth less said first depth.

8. The method of claim 1, further comprising:
forming another trench having said first depth and containing a third pair of substantially planar trench sidewalls in said semiconductor substrate at the same step as said forming of said trench; and
forming a protective dielectric layer within said another trench prior to said forming of said oxidation mask layer.

9. The method of claim 8, further comprising:
forming said protective dielectric layer within said trench; and
removing said protective dielectric layer within said trench from within said trench prior to said forming of said oxidation mask layer.

10. The method of claim 9, further comprising:
filling said trench and said another trench with a dielectric material;
planarizing said dielectric material employing a dielectric pad layer as a stopping layer; and
recessing said dielectric material to a height that is substantially flush with a top surface of said semiconductor substrate.

11. The method of claim 1, wherein said protective dielectric layer and said thermal oxide collar comprise silicon oxide, and protective dielectric layer and said thermal oxide collar are removed at a same etch step.

12. A semiconductor structure comprising:
a first shallow trench isolation (STI) structure comprising a dielectric material, located in a semiconductor substrate, and containing a first pair of substantially planar STI sidewalls separated by a first width and a first STI bottom surface located at a first depth, wherein said first pair of substantially planar STI sidewalls extends from a top surface of said semiconductor substrate to said first STI bottom surface; and
a second shallow trench isolation (STI) structure comprising said dielectric material and located in said semiconductor substrate and having an upper portion and a lower portion, wherein said upper portion contains a second pair of substantially planar STI sidewalls separated by a second width and extending from said top surface to a second depth, and wherein said lower portion contains a third pair of substantially planar STI sidewalls separated by a third width and extending from said second depth to a third depth and adjoining a second STI bottom surface at said third depth, and wherein said third width is greater than said second width.

13. The semiconductor structure of claim 12, wherein said third depth is greater than said first depth, and wherein said second depth is less than said first depth.

14. The semiconductor structure of claim 12, wherein said third width less said second width is less than twice said third depth less said first depth.

15. The semiconductor structure of claim 12, wherein said first STI bottom surface and said second STI bottom surface are substantially horizontal and planar.

16. The semiconductor structure of claim 12, further comprising:
at least one semiconductor device abutting said first pair of substantially planar STI sidewalls and extending from said top surface to a depth below said second depth; and
at least another semiconductor device abutting said second pair of substantially planar STI sidewalls and located above said second depth.

17. A semiconductor structure comprising:
a first trench located in a semiconductor substrate and containing a first pair of substantially planar trench sidewalls separated by a first width and a first trench bottom surface located at a first depth, wherein said first pair of substantially planar trench sidewalls extends from a top surface of said semiconductor substrate to said first trench bottom surface; and
a second trench located in said semiconductor substrate and having an upper portion and a lower portion, wherein said upper portion contains a second pair of substantially planar trench sidewalls separated by a second width and extending from said top surface to a second depth, and wherein said lower portion contains a third pair of substantially planar trench sidewalls separated by a third width and extending from said second depth to a third depth and adjoining a second trench bottom surface at said third depth, and wherein said third width is greater than said second width.

18. The semiconductor structure of claim 17, wherein said third depth is greater than said first depth, and wherein said second depth is less than said first depth.

19. The semiconductor structure of claim 17, wherein said third width less said second width is less than twice said third depth less said first depth.

20. The semiconductor structure of claim 17, wherein said first trench bottom surface and said second trench bottom surface are substantially horizontal and planar.
